(19) United States
(12) Patent Application Publication
(10) Pub. No.: US 2015/0241288 A1
(43) Pub. Date: Aug. 27, 2015

(54) CONFORMAL ELECTRONICS WITH DEFORMATION INDICATORS

(71) Applicant: MC10. INC., CAMBRIDGE, MA (US)

(72) Inventors: BRYAN KEEN, WESTMINSTER, MA (US); JACOB FENUCCIO, BOSTON, MA (US); MELISSA CERUOLO, SWAMPSCOTT, MA (US); SANJAY GUPTA, BEDFORD, MA (US); RYAN WHITE, SALEM, MA (US)

(21) Appl. No.: 14/630,335

(22) Filed: Feb. 24, 2015

Related U.S. Application Data
(60) Provisional application No. 61/943,614, filed on Feb. 24, 2014.

(51) Int. Cl. G01L 1/16; G01R 31/28; G08B 7/06; H05K 7/06

(52) U.S. Cl. CPC G01L 1/16; H05K 7/06; G01R 31/2855; G08B 7/06

(57) ABSTRACT

A conformal electronic device with a deformation indicator is disclosed. The conformal electronic device includes electronics operable to measure one or more parameters of an object on which the conformal device is disposed on or proximate to, a conformal layer that encapsulates the electronics, and a deformation indicator configured to indicate a deformation threshold of the electronics, the conformal layer, the conformal device, or a combination thereof.

### CROSS-REFERENCE AND CLAIM OF PRIORITY TO RELATED APPLICATION

This application claims the benefit of priority to U.S. Provisional Patent Application No. 61/943,614, which was filed on Feb. 24, 2014, and is incorporated herein by reference in its entirety and for all purposes.

### TECHNICAL FIELD

Aspects of the present disclosure relate generally to flexible and/or stretchable integrated circuit (IC) electronics. More particularly, aspects of this disclosure relate to flexible and/or stretchable conformal electronic devices.

### BACKGROUND

Integrated circuits (ICs) are the cornerstone of the information age and the foundation of today's information technology industries. The integrated circuit, a.k.a. “chip” or “microchip,” is a set of interconnected electronic components, such as transistors, capacitors, and resistors, which are etched or imprinted onto a semiconducting material, such as silicon or germanium. Integrated circuits take on various forms including, as some non-limiting examples, sensors, microprocessors, amplifiers, flash memories, application specific integrated circuits (ASICs), static random access memories (SRAMs), digital signal processors (DSPs), dynamic random access memories (DRAMs), erasable programmable read only memories (EPROMs), and programmable logic. Integrated circuits are used in innumerable products, including computers (e.g., personal, laptop, and tablet computers), smartphones, flat-screen televisions, medical instruments, telecommunication and networking equipment, airplanes, watercraft, and automobiles.

Advances in integrated circuit technology and microchip manufacturing have led to a steady decrease in chip size and an increase in circuit density and circuit performance. The scale of semiconductor integration has advanced to the point where a single semiconductor chip can hold tens of millions to over a billion devices in a space smaller than a U.S. penny. Moreover, the width of each conducting line in a modern microchip can be made as small as a fraction of a nanometer. The operating speed and overall performance of a semiconductor chip (e.g., clock speed and signal net switching speeds) has concomitantly increased with the level of integration. To keep pace with increases in on-chip circuit switching frequency and circuit density, semiconductor packages currently offer higher pin counts, greater power dissipation, more protection, and higher speeds than packages of just a few years ago.

The advances in integrated circuits have led to related advances within other fields. One such field is sensors. Advances in integrated circuits have allowed sensors to become smaller and more efficient, while simultaneously becoming more capable of performing complex operations. Other advances in the field of sensors and circuitry in general have led to wearable circuitry, a.k.a. “wearable devices” or “wearable systems.” Within the medical field, as an example, wearable devices have given rise to new methods of acquiring, analyzing, and diagnosing medical issues with patients, by having the patient wear a sensor that monitors specific characteristics. Related to the medical field, other wearable devices have been created within the sports and recreational fields for the purpose of monitoring physical activity and fitness. For example, a user may wear a device, such as a wearable running coach, to measure the distance traveled during an activity (e.g., running, walking, etc.), and measure the kinematics of the user's motion during the activity.

Wearable circuitry, devices, and systems rely on being deformable, such as flexible, bendable, compressible, twistable, stretchable, etc., to conform to an object. Typically, such wearable circuitry includes electronics encapsulated in a conformal layer. While the conformal layer can deform, the electronics within the conformal layer may not deform to the same extent as the conformal layer. Additionally, although both the conformal layer and the electronics can deform, these components still have deformation thresholds above which the components may become damaged and/or fail. Thus, such wearable circuitry, devices, and systems are prone to being damaged and/or destroyed from being deformed beyond the tolerances of the constituent components.

A need exists, therefore, for conformal electronic devices that include indicators that indicate a deformation threshold.

### SUMMARY

According to aspects of the present disclosure, a conformal electronic device worn on a user includes one or more indicators that indicate one or more deformation thresholds with respect to deforming the conformal electronic device.

According to certain aspects of the present disclosure, a conformal electronic device includes electronics operable to, with respect to an object on which the conformal device is disposed on or proximate to, measure one or more parameters of the object. The conformal electronic device further includes a conformal layer that encapsulates the electronics. The conformal electronic device also includes a deformation indicator configured to indicate a deformation threshold of the electronics, the conformal layer, the conformal device, or a combination thereof.

According to further aspects of the present disclosure, a conformal electronic device is disclosed that includes a conformal substrate. The conformal electronic device further includes one or more electronic components disposed on and/or within the conformal substrate, the one or more electronic components being operable to measure one or more parameters of a user wearing the conformal device. Additionally, the conformal electronic device includes a strain limiter operable to vary a displacement of the conformal substrate, the one or more electronic components, the conformal electronic device, or a combination thereof in response to a deformation applied to the conformal electronic device.

In accordance with additional aspects of the present concepts, a conformal electronic device includes one or more electronic components, the one or more electronic components being operable to measure one or more parameters of a user wearing the conformal device. The conformal electronic device further includes a conformal encapsulation layer surrounding the one or more electronics. In addition, the conformal electronic device includes a deformation indicator, the deformation indicator being configured to indicate a deformation threshold of the conformal electronic device. The encapsulation layer of the conformal electronic device is operable to reveal the deformation indicator at the deformation threshold of the conformal electronic device.

The above summary is not intended to represent each embodiment or every aspect of the present disclosure. Rather, the foregoing summary merely provides an exemplification of some of the novel aspects and features set forth herein. The above features and advantages, and other features and advantages of the present disclosure, will be readily apparent from the following detailed description of representative embodiments and modes for carrying out the present invention when taken in connection with the accompanying drawings and the appended claims.

### BRIEF DESCRIPTION OF THE DRAWINGS

The disclosure will be better understood from the following description of exemplary embodiments together with reference to the accompanying drawings, in which:

FIG. 1 shows a conformal electronic device, in accord with some aspects of the present concepts.

FIG. 2A shows a conformal electronic device, in accord with some additional aspects of the present disclosure.

FIGS. 2B and 2C show perspective views of a stretching deformation of the conformal electronic device of FIG. 2A, in accord with aspects of the present concepts.

FIG. 3 shows a perspective view of an exemplary deformation type of a conformal electronic device, in accord with aspects of the present concepts.

FIG. 4 shows a perspective view of an exemplary deformation type of the conformal electronic device of FIG. 3, in accord with additional aspects of the present concepts.

FIGS. 5A and 5B show perspective views of an exemplary deformation type applied to the conformal electronic device of FIG. 3, in accord with additional aspects of the present concepts.

FIG. 6 shows a perspective view of an indicator of a conformal electronic device, in accord with additional aspects of the present concepts.

FIG. 7 shows a top view of an indicator of a conformal electronic device, in accord with additional aspects of the present concepts.

FIGS. 8A and 8B show perspective views of an indicator of a conformal electronic device, in accord with additional aspects of the present concepts.

FIGS. 9A-9C show perspective views of an indicator of a conformal electronic device, in accord with additional aspects of the present concepts.

FIGS. 10A and 10B show views of an indicator of a conformal electronic device, in accord with additional aspects of the present concepts.

FIGS. 11A and 11B show views of an indicator of a conformal electronic device, in accord with additional aspects of the present concepts.

FIGS. 12A and 12B show views of an indicator of a conformal electronic device, in accord with additional aspects of the present concepts.

FIG. 13A shows a strain limiter within a conformal electronic device, in accord with aspects of the present concept.

FIG. 13B shows a plot of displacement versus applied force to a strain limiter, in accord with aspects of the present concepts.

FIG. 14 shows a conformal electronic device with a strain limiter and indicator, in accord with aspects of the present concepts.

The present disclosure is susceptible to various modifications and alternative forms, and some representative embodiments have been shown by way of example in the drawings and will be described in detail herein. It should be understood, however, that the invention is not intended to be limited to the particular forms disclosed. Rather, the disclosure is to cover all modifications, equivalents, and alternatives falling within the spirit and scope of the invention as defined by the appended claims.

### DETAILED DESCRIPTION OF THE ILLUSTRATED EMBODIMENTS

This disclosure is susceptible of embodiment in many different forms. There are shown in the drawings, and will herein be described in detail, representative embodiments with the understanding that the present disclosure is to be considered as an exemplification of the principles of the present disclosure and is not intended to limit the broad aspects of the disclosure to the embodiments illustrated. To that extent, elements and limitations that are disclosed, for example, in the Abstract, Summary, and Detailed Description sections, but not explicitly set forth in the claims, should not be incorporated into the claims, singly or collectively, by implication, inference, or otherwise. For purposes of the present detailed description, unless specifically disclaimed: the singular includes the plural and vice versa; and the word “including” means “including without limitation.” Moreover, words of approximation, such as “about,” “almost,” “substantially,” “approximately,” and the like, can be used herein in the sense of “at, near, or nearly at,” or “within 3-5% of,” or “within acceptable manufacturing tolerances,” or any logical combination thereof, for example.

The indefinite articles “a” and “an,” as used herein in the specification, unless clearly indicated to the contrary, should be understood to mean “at least one.”

The phrase “and/or,” as used herein in the specification, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B,” when used in conjunction with open-ended language such as “comprising” can refer, in one embodiment, to A only (optionally including elements other than B); in another embodiment, to B only (optionally including elements other than A); in yet another embodiment, to both A and B (optionally including other elements).

As used herein in the specification, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements).

The terms “flexible,” “stretchable,” and “bendable,” including roots and derivatives thereof, when used as an adjective to modify electronics, electronic components, electrical circuitry, electrical systems, and electrical devices or apparatuses, are meant to encompass electronics that comprise at least some components having pliant or elastic properties such that the circuit is capable of being flexed, stretched, and/or bent, respectively, without tearing or breaking or compromising their electrical characteristics. These terms are also meant to encompass circuitry having components (whether or not the components themselves are individually stretchable, flexible, or bendable) that are configured in such a way so as to accommodate and remain functional when applied to a stretchable, bendable, inflatable, or otherwise pliant surface. In configurations deemed “extremely stretchable,” the circuitry is capable of stretching and/or compressing and/or bending while withstanding high translational strains, such as in the range of −100% to 100%, −1000% to 1000%, and, in some embodiments, up to −100,000% to +100,000%, and/or high rotational strains, such as to an extent of 180° or greater, without fracturing or breaking and while substantially maintaining electrical performance found in an unstrained state.

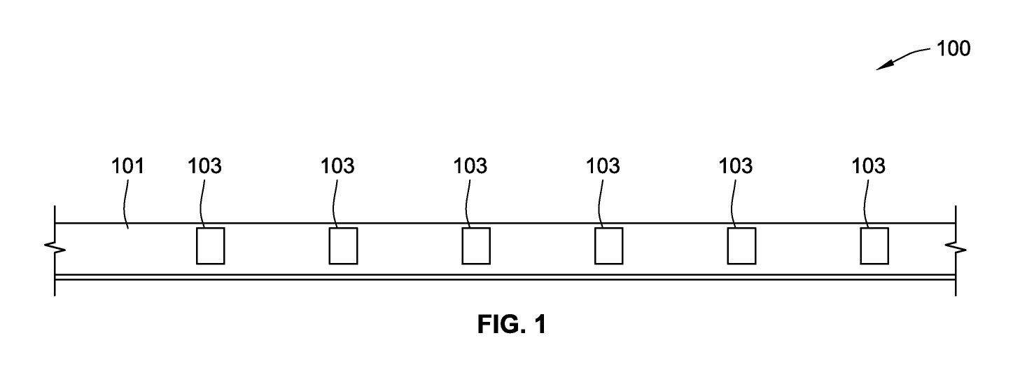

FIG. 1 shows a conformal electronic device 100, in accord with aspects of the present disclosure. The conformal electronic device 100 includes electronics (not shown) surrounded by an encapsulation layer 101 (or substrate). The encapsulation layer 101 can be formed, for example, of a soft, flexible, and/or otherwise stretchable non-conductive and/or conductive material that can conform to the contour of a surface on which the conformal electronic device 100 is disposed. Examples of such surfaces can include, but are not limited to, a body part of a user, such as a human or an animal, or any other object. Suitable materials of the encapsulation layer 101 include, for example, a polymer or a polymeric material. Non-limiting examples of applicable polymers or polymeric materials include, but are not limited to, silicone, both non-conductive and selectively conductive (e.g., one or more conductive areas and/or entirely conductive), or polyurethane. Other non-limiting examples of applicable polymers or polymeric materials include plastics (including a thermoplastic, a thermoset plastic, or a biodegradable plastic), elastomers (including a thermoplastic elastomer, a thermoset elastomer, or a biodegradable elastomer), and fabrics (including a natural fabric or a synthetic fabric), such as but not limited to acrylates, acetal polymers, cellulosic polymers, fluoropolymers, nylons, polyacrylonitrile polymers, polyamide-imide polymers, polyarylates, polybenzimidazole, polybutylene, polycarbonate, polyesters, polyetherimide, polyethylene, polyethylene copolymers and modified polyethylenes, polyketones, poly(methyl methacrylate), polymethylpentene, polyphenylene oxides and polyphenylene sulfides, polyphthalamide, polypropylene, polyurethanes, styrenic resins, sulphone based resins, vinyl-based resins, or any combinations of these materials. In an example, a polymer or polymeric material herein can be a UV curable polymer, such as but not limited to a UV curable silicone.

The encapsulation layer 101 can be formed using any suitable process, for example, casting, molding, stamping, or any other known or hereinafter developed fabrication methods. Furthermore, the encapsulation layer 101 can include a variety of optional features, such as holes, protrusions, grooves, indents, non-conducting interconnects, or any other features. By way of non-limiting example, the encapsulation layer 101 can be formed using an overmolding process. In general, overmolding allows for a previously fabricated part to be inserted into a mold cavity in an injection molding machine that forms a new plastic part, section, or layer on or around the first part. One such overmolding process includes directly casting a liquid material capable of forming the encapsulation layer 101 on the electronics. The liquid material can then be cured (e.g., cool and solidify). Curing can be performed under any suitable conditions, for example, by applying pressure on the casted liquid material, heating the substrate, and/or applying a vacuum.

As another example, the electronics can be embedded in the encapsulation layer 101 using a lamination process. For instance, the encapsulation layer 101 can be pre-casted into a sheet. A liquid adhesive (e.g., the uncured liquid material used to form the encapsulation layer, or any other suitable adhesive) can then be disposed on the electronics. The encapsulation layer 101 can be then disposed on the adhesive and pressure applied to squeeze out excess adhesive. The adhesive can then be cured to fixedly couple the encapsulation layer 101 to at least a portion of the electronics, thereby forming conformal electronic device 100 of FIG. 1.

The electronics of the conformal electronic device 100 can be configured to deform, such as being flexible, bendable, stretchable, twistable, and/or compressible. Accordingly, the electronics of the conformal electronic device 100 can, at least in part, conform to a surface of an object, such as the skin of a user. According to some embodiments, the electronics include a plurality of device “islands” interconnected by one or more interconnects. The encapsulated discrete islands (or “packages”) mentioned herein are discrete operative devices, e.g., arranged in a “device island” arrangement, and are themselves capable of performing the functionality described herein, or portions thereof. Such functionality of the operative devices can include, for example, integrated circuits, physical sensors (e.g., temperature, pH, light, radiation, etc.), biological sensors, chemical sensors, amplifiers, A/D and D/A converters, optical collectors, electro-mechanical transducers, piezoelectric actuators, light emitting electronics (e.g., LEDs), and any combination thereof. A purpose and an advantage of using one or more standard ICs (e.g., CMOS on single crystal silicon) is to use high-quality, high-performance, and high-functioning circuit components that are readily accessible and mass-produced with well-known processes, and which provide a range of functionality and generation of data far superior to that produced by passive means.

The ability of the electronics to flex, bend, stretch, twist, and/or compress can be achieved, at least in part, by the interconnects between the device islands, while the device islands can remain more stiff. The device islands, and electronics in general, are configured to perform sensing, measuring, and/or otherwise quantifying one or more parameters of an object that is proximate to the conformal electronic device 100. The electronics allow for the conformal electronic device 100 to provide conformal sensing capabilities, providing mechanically transparent close contact with a surface to improve measurement and/or analysis of physiological information or other information associated with the at least one object. By way of example, the object can be a user wearing the conformal electronic device 100. The user can be a human or a non-human animal. The user can wear the conformal electronic device 100 on a body part, such as on the arm, the leg, the chest, the waist, the head, etc. to obtain one or more measurements of one or more parameters with respect to the body part. The one or more measurements can be, for example, and without limitation, acceleration measurements, muscle activation measurements, heart rate measurements, electrocardiogram (ECG) measurements, electrical activity measurements, temperature measurements, hydration level measurements, neural activity measurements, conductance measurements, environmental measurements, pressure measurements, and a combination thereof.

The electronics of the conformal electronic device 100 can include one or more passive electronic components and/or one or more active electronic components. The passive and/or active electronic components provide a variety of sensing modalities. By way of example, and without limitation, such components can include a transistor, an amplifier, a photodetector, a photodiode array, a display, a light-emitting device, a photovoltaic device, a sensor, a light-emitting diode, a semiconductor laser array, an optical imaging system, a large-area electronic device, a logic gate array, a microprocessor, an integrated circuit, an electronic device, an optical device, an opto-electronic device, a mechanical device, a microelectromechanical device, a nanoelectromechanical device, a microfluidic device, a thermal device, and other device structures.

According to some embodiments, the electronics can use the one or more parameters in analyses for various applications, such as medical diagnosis, medical treatment, physical activity, sports, physical therapy, and/or clinical purposes. By way of example, data of the one or more parameters gathered by the conformal electronic device 100, along with data gathered based on sensing other physiological measures of the body, can be analyzed to provide useful information related to medical diagnosis, medical treatment, physical state, physical activity, sports, physical therapy, and/or clinical purposes. In combination with pharmaceuticals, the data of the one or more parameters can be used to monitor and/or determine subject issues including compliance with and/or effects of treatment regimens. Moreover, the size, weight, and/or placement of the conformal electronic device 100 do not impede the sensing, measuring, or otherwise quantifying of the one or more parameters.

By way of a specific example, and without limitation, the conformal electronic device 100 described herein is operable to monitor the body motion and/or muscle activity of a user, and to gather measured data values indicative of monitoring. The monitoring can be performed in real-time, at different time intervals, and/or when requested. In addition, the conformal electronic device 100 can be configured to store the measured data values to memory within the conformal electronic device 100 and/or to communicate (e.g., transmit) the measured data values to an external memory or other storage device, a network, and/or an off-board computing device. By way of example, the external storage device can be a server, including a server in a data center. Non-limiting examples of a computing device applicable to any of the described principles herein include smartphones, tablets, laptops, slates, e-readers (or other electronic readers), hand-held or worn computing devices, an Xbox®, a Wii®, or other game systems.

According to some embodiments, the one or more components are electrically connected by interconnects. The interconnects can be flexible, bendable, stretchable, and/or expandable and electrically interconnect the components of the electronics to form one or more electronic circuits within the conformal electronic device 100. The interconnects can be formed of any electrically conductive material, such as, for example, copper, silver, gold, or other conductive metals. According to some embodiments, the interconnects can be formed of a semiconductor material, such as silicon, germanium, gallium, silicon germanium, etc., and can be formed according to various patterning techniques, such as photolithography of a semiconductor material.

As illustrated in FIG. 1, according to some embodiments, the conformal electronic device 100 can be configured as a thin, flexible, and/or stretchable band. However, the shape and configuration of the conformal electronic device 100 can vary without departing from the spirit and scope of the present disclosure. According to some embodiments, and without limitation, such configurations can include, for example, an elastomeric patch that can be applied to a user, such as human skin (for example, using an adhesive layer). Such elastomeric patches can include conformal electrodes (e.g., as one or more components of the electronics) disposed in or on a flexible and/or stretchable substrate (e.g., the encapsulation layer 101).

Non-limiting examples of a conformal electric device 100, or a device that can include a conformal electronic device 100 (e.g., as a sub-device), include a wearable electronic device, a wearable band, or any other equivalent band, such as but not limited to a NIKE+FUELBAND® (Nike, Inc.), a FITBIT® (Fitbit Inc.), an UP™ wristband (Jawbone), or a LIVESTRONG® (Livestrong Foundation). Moreover, a conformal electronic device 100 according to the aspects disclosed herein can be incorporated into any product in which deformation limiting control, regulation, and/or indication would be desirable.

The conformal electronic device 100 is configured to be deformable (e.g., flexible, bendable, compressible, stretchable, twistable, etc.) to at least be able to conform to the surface of an object, such as the skin of a user. Despite the conformal nature of the conformal electronic device 100, the conformal electronic device 100 has certain deformation thresholds. Thus, one or more elements of the conformal electronic device 100, such as the encapsulation layer 101 and/or the electronics, can fail from being deformed beyond the deformation thresholds.

The deformation threshold of the conformal electronic device 100, and/or one or more elements of the conformal electronic device 100, is a quantified amount of deformation beyond a relaxed, non-deformed state of the conformal electronic device 100. According to some embodiments, the quantified amount is a range of deformation. By way of example, and without limitation, the upper limit of the range can be an amount of deformation immediately preceding an amount of deformation that causes damage to the conformal electronic device 100. Such an amount of deformation that causes damage to the conformal electronic device 100 constitutes a deformation limit. Alternatively, the upper limit of the range can be the deformation limit.

According to some embodiments, the deformation threshold can be a specific amount of deformation, such as an amount of deformation immediately preceding the deformation limit, or the deformation limit itself. According to some embodiments, the deformation threshold can be a range above the deformation limit, such as a range in which the lower limit of the range is above the deformation limit. Alternatively, the deformation threshold can be a specific amount of deformation above the deformation limit.

To prevent damage to the conformal electronic device 100 caused by deformation, the conformal electronic device 100 includes an indicator 103. The indicator 103 is configured to indicate a deformation threshold of the conformal electronic device 100, or of one or more components of the conformal electronic device 100 (such as the electronics and/or the encapsulation layer 101). One or more properties of the indicator 103, alone or in relation to one or more properties of other elements of the conformal electronic device 100, are configured such that the indictor 103 appears, is audible, and/or provides a tactile response at the deformation threshold. Thus, the indicator 103 is configured to provide an indication of the deformation threshold of the conformal electronic device 100, and/or one or more elements of the conformal electronic device 100, prior to failure and/or breakage (or indication thereof) of the conformal electronic device 100, or one or more elements of the conformal electronic device 100. According to some embodiments, the indicator 103 can, in addition or in the alternative, generate and transmit an alert (e.g., a communication) to a device that is external to the conformal electronic device 100. The external device can then provide an indication based on the alert sent from the indicator 103 of the conformal electronic device 100.

The indicator 103 can be formed of various materials, such as metals, plastics, fabrics, etc., and can be formed according to various shapes. By way of example, and without limitation, an indicator 103 can be in the shape of a cube, a sphere, a strip, a band, etc. The indicator 103 can include various patterns on its exterior surface, such as lines, waves, zig-zags, etc. According to some embodiments, the indicator 103 is formed of a material with a high visibility based on, for example, a high reflectance, a specific color, etc. According to some embodiments, the indicator 103 can be formed of a flexible material or a rigid material. According to a flexible material, the indicator 103 can conform to the shape of the conformal electronic device 100. According to a rigid material, the indicator 103 can maintain its shape despite a deformation of the conformal electronic device 100, such as to provide a tactile indication of a deformation threshold of the conformal electronic device 100.

The deformation can be any type of mechanical manipulation of the conformal electric device 100, such as, but not limited to, stretching, compressing, bending, flexing, and/or twisting of the conformal electronic device 100. Such deformation can be in one or more axes, such as the x-axis, the y-axis, and/or the z-axis. Further, different types of deformation can occur within different axes, such as a stretching deformation occurring within the x-axis along with a compressive deformation occurring within the y-axis.

The indicator 103 can indicate the deformation threshold according to the variations discussed above. By way of example, and without limitation, the deformation indicator 103 can indicate a range of deformation in which the upper limit of the range is the deformation limit. The indicator 103 can alternatively indicate a deformation threshold in an amount of deformation immediately preceding a deformation limit. Accordingly, the indicator 103 can indicate that the conformal electronic device 100 is approaching and/or has reached the deformation limit.

Alternatively, or in addition, the deformation indicator 103 can indicate a deformation threshold to apply to a conformal electronic device 100. Such a deformation threshold can represent a specific amount of deformation required to activate and/or initiate one or more functions of the conformal electronic device 100. By way of example, such an indicator can indicate how much to stretch, bend, and/or twist the conformal electronic device 100 to trigger one or more functions of the conformal electronic device 100.

The indicator 103 indicates a deformation threshold according to one or more of a visual indication, an auditory indication, and/or a tactile indication. With respect to the indicator 103 generating and transmitting an alert to an external device, the alert can cause the external device to generate one or more of a visual indication, an auditory indication, and/or a tactile indication. With respect to a visual indication, and adverting back to FIG. 1, the conformal electronic device 100 includes an indicator 103. The indicator 103 is disposed proximate to the surface of the encapsulation layer 101 such that a visual indication is provided based on a thinning of the encapsulation layer 101 (e.g., a portion of the encapsulation layer 101 configured to exhibit the desired degree of thinning). As the encapsulation layer 101 thins, the indicator 103 is revealed beneath the encapsulation layer 101. Revealing the indicator 103 serves as a visual indication to the user that the conformal electronic device 100 has reached a deformation threshold.

One or more properties of the indicator 103 and the encapsulation layer 101 are controlled such that the indicator 103 is revealed at the deformation threshold. The thickness and the transparency of the encapsulation layer 101, and the visibility and depth of the deformation indicator 103 are controlled such that the deformation indicator 103 is revealed when a specified amount of deformation is applied to the conformal electronic device 100. The specified amount and/or type are selected such that the indication is provided, for example, prior to reaching a deformation limit.

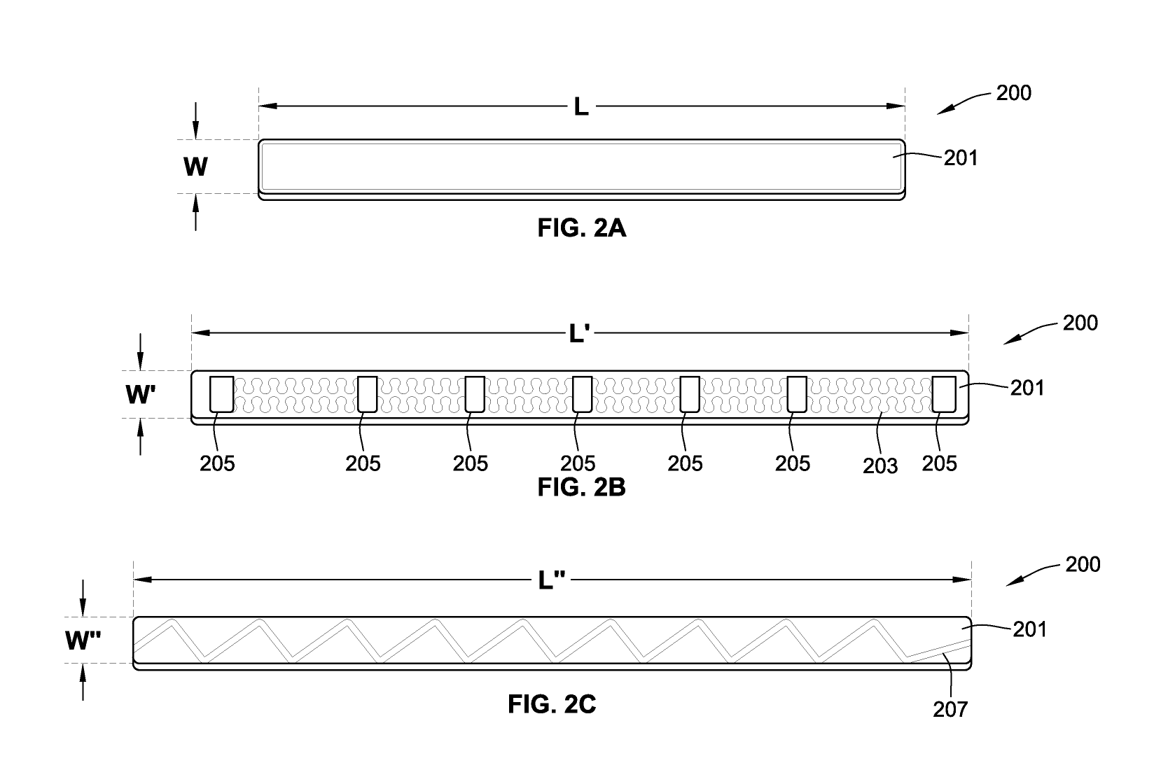

Based on the varying types and amounts of deformation that can be applied to the conformal electronic device 100, the type of indicator can vary. FIGS. 2A and 2B show perspective views of a stretching deformation of a conformal electronic device 200, in accord with aspects of the present concepts. The conformal electronic device 200 is similar to the conformal electronic device 100 of FIG. 1 in that it is a flexible, stretchable, and bendable band. Further, like the conformal electronic device 100, the conformal electronic device 200 includes an encapsulation layer 201 that encapsulates electronics (not shown) of the conformal electronic device 200. However, the conformal electronic device 200 includes a different deformation indicator 203 than the conformal electronic device 100 of FIG. 1.

Specifically, FIG. 2A shows the conformal electronic device 200 in an un-stretched state. In an un-stretched state, the conformal electronic device 200 has a length L and a width W. According to the conformal electronic device 200 being in the form of a band, the length L is greater than the width W. However, according to additional embodiments of the present concepts, the length L and the width W can vary such that the width W of a conformal electronic device can be equal to or greater than the length L. By way of example, and without limitation, the length L and the width W of the conformal electronic device 200 in an un-stretched state can be 125 millimeters (mm) and 10 mm, respectively. The conformal electronic device 200 can also have a specified thickness, such as 1.75 mm.

Adverting to FIG. 2B, and as described above, the conformal electronic device 200 includes an indicator 203. The indicator 203 is operable to provide a visual indication to a user to discontinue deforming the conformal electronic device 200 according to a specific type and/or amount of deformation. By way of example, and without limitation, FIG. 2B illustrates the conformal electronic device 200 in a stretched state relative to FIG. 2A (e.g., deformed according to stretching). In a stretched state, the length L′ and the width W′ of the conformal electronic device 200 can be, for example, 150 mm and 9 mm, respectively. Moreover, the thickness of the conformal electronic device 200 can be, for example, 1.5 mm in the stretched state. As the conformal electronic device 200 is stretched, the indicator 203 appears with greater visual contrast. The indicator 203, in conjunction with the encapsulation layer 201, is configured to indicate to a user that the conformal electronic device 200 has reached a deformation threshold. That is, as the conformal electronic device 200 is stretched, the thickness decreases. As the thickness decreases, the indicator 203 becomes visible.

According to some embodiments, the encapsulation layer 201 is formed thinner corresponding to the location of the indicator 203 to aid in the visibility of the indicator 203. By way of example, the thickness of the encapsulation layer 201 can be reduced to facilitate a higher amount of visual display of the indicator 203 upon deformation of the conformal electronic device 200. As a non-limiting example, the thickness of the encapsulation layer 201 can reduce by 0.25 mm, locally (e.g., corresponding to the location of the indicator) or along its entirety, to achieve increased visual indication of the indicator 203.

The indicator 203 becoming visible is an indication to the user to discontinue deforming the conformal electronic device 200. According to the embodiment illustrated in FIG. 2B, the indicator 203 becoming visible indicates to the user to stop stretching the conformal electronic device 200 prior to, or at the point of, the conformal electronic device 200 reaching a lengthwise deformation, such as prior to causing damage to the conformal electronic device 200 (e.g., reaching the deformation limit).

As illustrated, the indicator 203 can be in the shape of serpentine interconnects between device islands 205 of the electronics. The serpentine interconnects can be active, such as electrically interconnecting one or more components of the electronics within the conformal electronic device 200. By way of example, the serpentine interconnects can electrically connect the device islands 205. Alternatively, the serpentine interconnects can be passive and solely function as an indicator, while not electrically interconnecting the device islands 205 of the electronics.

The shape and/or pattern of the indicator can vary without departing from the spirit and scope of the present concepts. According to some embodiments, the pattern of an indicator may serve to further indicate to stop deforming the conformal electronic device, such as by providing one or more indicia that further indicate to stop deforming the conformal electronic. By way of example, the indicia of the indicator may spell a word, such as STOP, that appears as the deformation reaches a specified deformation threshold. Accordingly, by the indicator appearing, alone, the user is indicated to stop the deformation. The indication is emphasized further by the indicia of the pattern of the indicator, itself, further identifying for the user to stop.

Although illustrated and described with respect to FIGS. 1, 2A, and 2B as being an object or pattern integrated within a conformal electronic device, an indicator can come in various styles without departing from the spirit and scope of the present disclosure. According to some embodiments, one or more indicators can include cracks or other small features or imperfections within an encapsulation layer. In a non-deformed state, the cracks or other small features or imperfections are not visible. However, upon reaching, for example, a deformation threshold, the cracks or other small features or imperfections become visible to indicate an approaching deformation limit.

Adverting to FIG. 2C, FIG. 2C shows the conformal electronic device 200 with indicator 207 in the encapsulation layer 201, in accord with aspects of the present concepts. In the initial un-deformed state shown in FIG. 2A, such as in an un-stretched state, the conformal electronic device 200 exhibits a smooth surface. In a deformed state, such as a stretched state, the conformal electronic device 200 exhibits the indicator 207 as small molded cracks and/or gaps in the encapsulation layer 201. The molded cracks and/or gaps are designed to appear at a deformation threshold to provide an indication to the user. By way of example, at a specified deformation threshold, the encapsulation layer 201 exhibits the indicator 207 as small cracks that open as the conformal electronic device 200 is deformed. In addition, or in the alternative, to stretching, the cracks can appear during twisting, bending, or other types of deformation. Thus, in addition to indicators being encapsulated by an encapsulation layer (e.g., encapsulation layer 101 and 201), the indicators can further be within or constitute part of the encapsulation layer, such as the above-described molded cracks and/or gaps.

According to some embodiments, the conformal electronic device 200 can include only the indicator 203 or only the indicator 207. Alternatively, according to some embodiments, the conformal electronic device 200 can include both the indictor 203 and the indicator 207. According to some embodiments, the indictor 203 and the indicator 207 can be configured to appear at the same deformation threshold, such as a deformation threshold below the deformation limit. Alternatively, according to some embodiments, each specific indicator can be configured to appear at different deformation thresholds. By way of example, the deformation threshold at which the indicator 203 appears can be lower than the deformation threshold at which the indicator 207 appears. Accordingly, with respect to stretching, as an example, as the user stretches the conformal electronic device 200, initially the indicator 203 can appear to inform the user to discontinue the deformation. If the user continues to deform the conformal electronic device 200, at a second, higher deformation threshold, the indicator 207 can appear to further indicate to the user to discontinue the deformation of the conformal electronic device 200.

Accordingly, the conformal electronic device 200 is stretched further in FIG. 2C relative to FIG. 2B. In the further stretched state of FIG. 2C, the length L″ and the width W″ of the conformal electronic device 200 can be, for example, 125 mm and 8 mm, respectively. Moreover, the thickness of the conformal electronic device 200 in FIG. 2C can, for example, be 1.25 mm in the stretched state.

According to some embodiments, the indicator 203 can still be visible when the indicator 207 is visible. Alternatively, according to some embodiments, the indicator 203 can become not visible when the indictor 207 is visible (as shown in FIG. 2C).

According to some embodiments, the controlled cracks of the indicator 207 can at least partially reduce the stress on the conformal electronic device 200 caused by the deformation. The cracks of the indicator 207 can release stress in, for example, the encapsulation layer 201 in a controlled manner to relieve some of the applied stress.

As described above, an indicator can indicate approaching and/or reaching a deformation threshold. According to some embodiments, an indicator can indicate a deformation threshold that is above a deformation limit of the conformal electronic device, such as when a user has deformed the conformal electronic device beyond the deformation limit and damaged the device. While an indicator that indicates a deformation threshold below the deformation limit may return to a normal, non-indicative state, such as when the deformation is discontinued, an indicator of a deformation threshold above the deformation limit does not return to a normal, non-indicative state. Such an indicator may be considered a permanent indicator once revealed. According to some embodiments, one or more permanent indicators can include, for example, a thread that breaks, either partially or entirely, upon reaching a deformation threshold, a fabric with built-in fault regions, such as nylon mesh, or other similar features that rupture when the conformal electronic device is deformed to a deformation threshold.

The above-described indicators represent exemplary visual indicators. According to some embodiments, an indicator can provide an auditory indication of a deformation threshold, such as approaching a deformation threshold and/or exceeding a deformation threshold. By way of example, an indicator can emit a cracking sound as an auditory indication of when a conformal electronic device is subjected to a deformation threshold below the deformation limit. Such an indicator can include, for example, a material, such as, for example, a nylon mesh, that generates a cracking and/or tearing sound as a conformal electronic device is deformed.

According to some embodiments, the nylon mesh (or other material) is selected according to a deformation threshold of the nylon mesh relative to the deformation threshold of the conformal electronic device and/or one or more components of the conformal electronic device, such as the interconnects of the electronics. The auditory indicator is selected to have a deformation threshold that is less than the deformation threshold of the conformal electronic device 100 and/or the one or more components such that the auditory indicator provides the auditory indication prior to the conformal electronic device and/or the one or more components reaching their deformation limits. Thus, the user causing the deformation of the conformal electronic device can discontinue the deformation prior to causing damage to the conformal electronic device and/or the one or more components in response to the auditory indication.

According to some embodiments, an indicator can provide a tactile indication of deformation, such as of approaching the deformation limit and/or exceeding the deformation limit. Such tactile indication can be, for example, based on shape changes. The tactile indicator can cause a shape change near the surface of a conformal electronic device. The shape change can correspond to contours or outlines of an indicator within a conformal electronic device that cause a tactile change in the conformal electronic device that the user can feel. One or more features within the conformal electronic device can be integrated into the conformal electronic device as the tactile indicators. Non-limiting examples of the tactile indicators include, for example, serpentine, wavy, rippled, zig-zag and/or buckled tactile features.

According to some embodiments, active interconnects within the electronics of the conformal electronic device can constitute the tactile indicators. The interconnects may be active, conductive interconnects of the conformal electronic device that electrically connect one or more components. Alternatively, the interconnects can be passive, non-conducting and/or non-connected features.

By way of example, the interconnects can be disposed in a portion of the conformal electronic device proximate to the surface such that the contour or outline of the interconnects protrude when the conformal electronic device is deformed, such as when the conformal electronic device is deformed to a deformation threshold below the deformation limit.

According to some embodiments, an indicator can provide both a visual indication and a tactile indication. For example, interconnects can be disposed proximate to the surface such that the visual indication is provided based on out of plain deformation of the interconnects in conjunction with a thinning of the top layer (e.g., a portion of the encapsulation layer configured to exhibit the desired degree of thinning). This serves as a visual indication to the user that the conformal electronic device is nearing a deformation limit. Further, in combination with the thinning of the top layer, the indicator can cause a shape change, such as raising the surface (or preventing the surface from further thinning) above the indicator relative to the surface not above the indicator. The change in the contour of the conformal electronic device can be felt by the user as a tactile indicator.

A conformal electronic device as described herein can be configured to include any combination of one or more of an auditory indicator, a visual indicator, and a tactile indicator. According to some embodiments, the conformal electronic device can be configured such that deformation applied in different directions (e.g., rotational and linear directions) produces differing amounts of a visual indication and an auditory indication. The conformal electronic device can also include one or more components, such as a receiver and a transmitter, for transmitting one or more alerts (e.g., communications) to one or more external devices. By way of example, an indicator of a conformal electronic device can generate one or more alerts. The one or more alerts are transmitted to one or more external devices, such as via a wireless communication medium, and generate one or more of an auditory indicator, a visual indicator, and a tactile indicator at the one or more external devices based on the indicator.

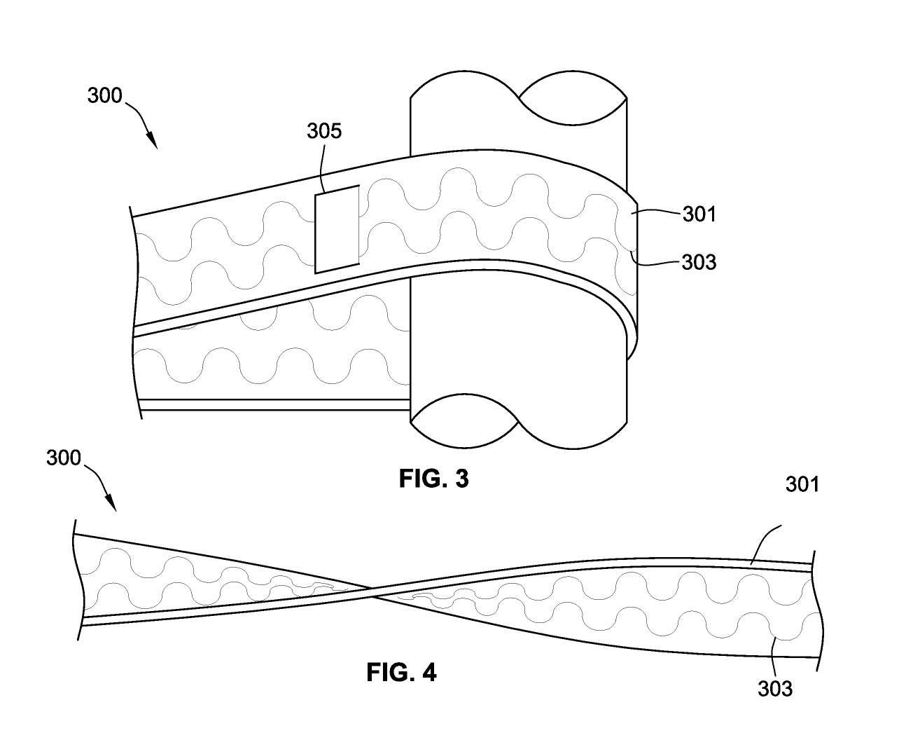

FIGS. 3-5B illustrate various examples of deformation types according to aspects of the present concepts. The conformal electronic device 300 illustrated in FIGS. 3-5B represents a conformal electronic device as described above.

Adverting to FIG. 3, the conformal electronic device 300 includes an encapsulation layer 301 that encapsulates an indicator 303 and electronics 305. One or more of the encapsulation layer 301 and the indicator 303 are configured such that a deformation (e.g., bending) of the conformal electronic device 300 to a deformation threshold reveals the indicator 303 (or causes the indicator 303 to become more visible) near the bent portion of the conformal electronic device 300. As illustrated, the indicator 303 can be in the shape of serpentine interconnects. The interconnects may serve the sole purpose of indicating deformation or may also electrically interconnect one or more components of the electronics 305. The indicator 303 provides a visual indication of reaching a deformation threshold and nearing a deformation limit of the conformal electronic device 300.

In addition to being a visible indicator, the indicator 303 of FIG. 3 may also be a tactile indicator. As the conformal electronic device 300 deforms (e.g., bends), the indicator 303 causes the surface of the encapsulation layer 301 above the indicator 303 to become raised relative to the encapsulation layer 301 not above the indicator 303. The contour caused by the raised encapsulation layer 301 is a visible indication, as well as a tactile indication, to the user that the conformal electronic device 300 is nearing (e.g., such as within 5-10% of the strain limit) and/or has reached a deformation threshold.

FIG. 4 shows another exemplary deformation type of the conformal electronic device 300 of FIG. 3 in accord with aspects of the present concepts. As illustrated in FIG. 4, the deformation is a twisting of the conformal electronic device 300. By way of example, twisting the conformal electronic device 300 to a twisting deformation threshold reveals the indicator 303 (or causes the indicator to become more visible) near the twisted portion of the conformal electronic device 300. Again, while illustrated and described as a serpentine pattern, the indicator 303 can be in the form of other shapes and patterns without departing from the spirit and scope of the present disclosure.

As illustrated and described in FIG. 3, the indicator 301 can provide both a visual and a tactile indication of the deformation threshold. As the conformal electronic device 300 deforms (e.g., twists in FIG. 4), the indicator 303 causes the surface of the encapsulation layer 301 above the indicator 303 to become raised relative to the encapsulation layer 301 not above the indicator 303. The contour caused by the raised encapsulation layer 301 is a visible indication, as well as a tactile indication, to the user of a deformation threshold of the conformal electronic device 300.

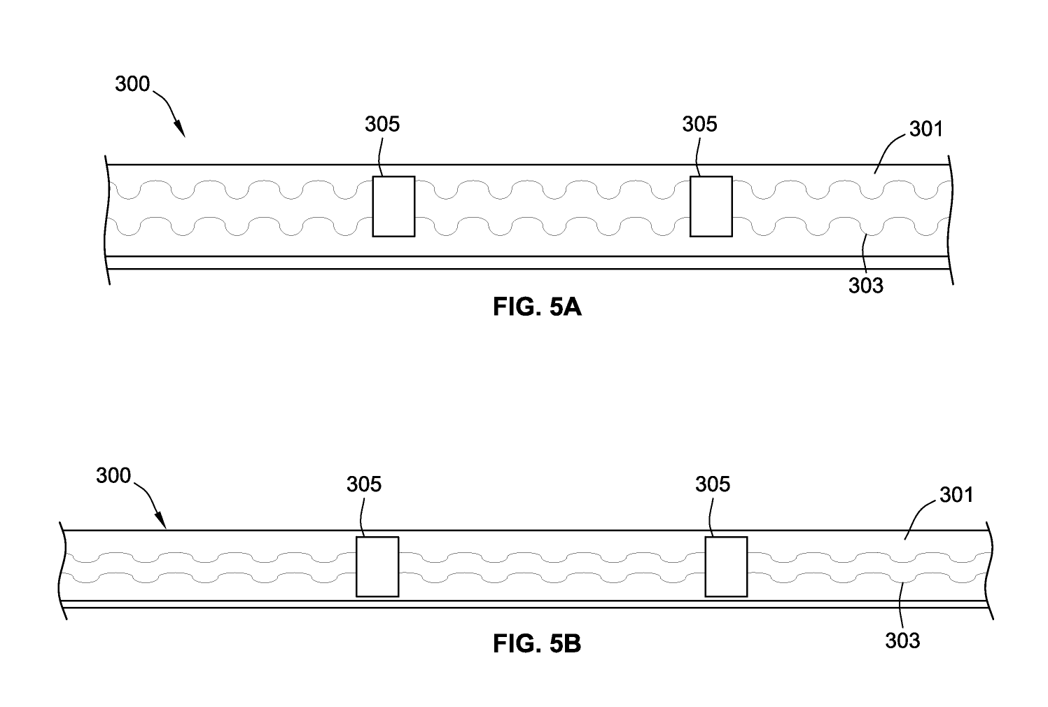

FIGS. 5A and 5B show perspective views of another exemplary deformation type applied to the conformal electronic device 300. FIG. 5A illustrates the conformal electronic device 300 in an un-stretched state, and FIG. 5B illustrates the conformal electronic device 300 in a stretched state. As illustrated in FIG. 5A relative to FIG. 5B, in an un-stretched state, the indicator 303 is not visible. However, in the stretched state, the indicator 303 becomes visible to indicate a deformation threshold of the conformal electronic device 300. In response, the user can discontinue deforming the conformal electronic device 300 to prevent damaging the conformal electronic device 300.

FIG. 6 shows a perspective view of an indicator 603 of a conformal electronic device 600, in accord with additional aspects of the present concepts. As discussed above, the pattern of an indicator may serve to further indicate to stop deforming the associated conformal electronic device, such as by providing one or more indicia. By way of example, FIG. 6 shows a perspective view of an indicator 603 that includes a pattern that serves to further indicate to a user to stop deforming the conformal electronic device. More specifically, the conformal electronic device 600 shown in FIG. 6 is at a deformation threshold in a deformed (e.g., stretched) state. The conformal electronic device 600 includes an encapsulation layer 601. Within the encapsulation layer 601 is an indicator 603. According to the deformed state of the conformal electronic device 600 and the encapsulation layer 601, the encapsulation layer 601 reveals the indicator 603. The indicator 603 includes the indicia STOP to inform the user further to stop deforming the conformal electronic device 600 upon reaching the deformation threshold. By way of example, the indicator 603 can be cuts formed within the encapsulation layer 601 that appear when the conformal electronic device 600 reaches a deformation threshold.

FIG. 7 shows a top view of another indicator 703 of a conformal electronic device 700, in accord with additional aspects of the present concepts. The conformal electronic device 700 includes an encapsulation layer 701. The top surface of the encapsulation layer 701 includes an indicator 703 in the form of angled cuts. The conformal electronic device 700 shown in FIG. 7 is at a deformation threshold, such as in a stretched state. In the stretched state, the encapsulation layer 701 reveals the indicator 703 in the form of angled cuts to inform the user to stop deforming the conformal electronic device 700. The indicator 703 constitutes both a visual indicator and a tactile indicator. By way of example, the cuts of the indicator 703 can reveal a lower layer of the encapsulation layer 701 that may be a different color. A user deforming the conformal electronic device 700 can both feel the cuts of the indicator 703 and see the difference in color as indications to stop deforming the conformal electronic device 700.

As described above, an indicator can indicate a deformation threshold that is above a deformation limit of the conformal electronic device, such as when a user has deformed the conformal electronic device beyond the deformation limit and damaged the device. By way of example, an indicator of a deformation threshold above the deformation limit does not return to a normal, non-indicative state. Such an indicator may be considered a permanent indicator once revealed.

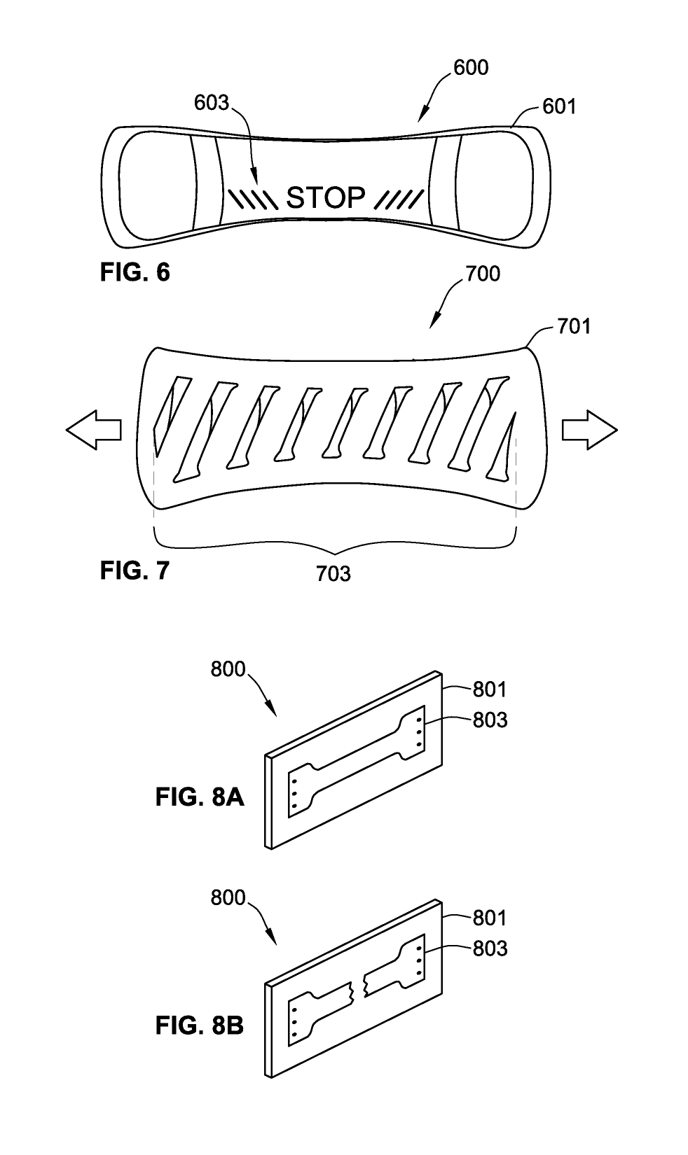

FIGS. 8A and 8B show perspective views of a permanent indicator 803 of a conformal electronic device 800, in accord with additional aspects of the present concepts. Adverting to FIG. 8A, the conformal electronic device 800 includes an encapsulation layer 801 and an indicator 803. The indicator 803 can be affixed to a top surface of the encapsulation layer 801, or may be embedded within the encapsulation layer 801.

In a relaxed state, and prior to being deformed to a deformation threshold, the indicator 803 is a single piece. By way of example, the indicator 803 can be a holographic film. Adverting to FIG. 8B, after a deformation of the conformal electronic device 800 that exceeds a deformation limit, the indicator 803 breaks to indicate that the conformal electronic device 800 experienced a deformation that exceeded the deformation limit. By way of example, the indicator 803 is configured to indicate a deformation threshold that exceeds the deformation limit of one or more of the conformal electronic device 800, the encapsulation layer 801, and the electronics (not shown). The indicator 803 can reveal that the conformal electronic device 800 may not be functioning correctly based on the conformal electronic device 800 experiencing a deformation that exceeded the deformation limit. Although shown as a distinct indicator according to a single pattern, the indicator 803 can come in the shape of various other patterns, such as an outline of a patch, without departing from the spirit and scope of the present disclosure.

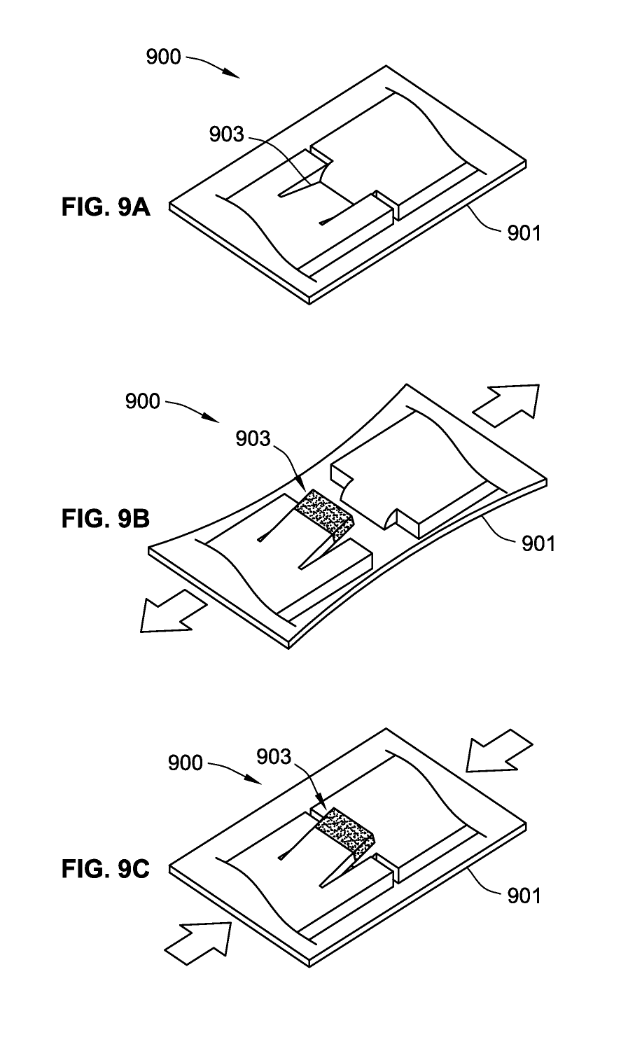

FIGS. 9A-9C show perspective views of another permanent indicator of a conformal electronic device, in accord with additional aspects of the present concepts. Adverting to FIG. 9A, the conformal electronic device 900 includes an encapsulation layer 901 and an indicator 903. The indicator 903 is in the form of a tab and is embedded within the encapsulation layer 901.

As shown in FIG. 9B, as the encapsulation layer 901 is stretched, the indicator 903 is also stretched such that the tab changes from an engaged state (FIG. 9A) to a disengaged state (FIG. 9B). The change in the indicator 903 from the engaged state of FIG. 9A to the disengaged state of FIG. 9B corresponds to a deformation threshold that exceeds the deformation limit of the indicator 903 (in addition to, for example, one or more components of the conformal electronic device 900).

Adverting to FIG. 9C, even though the encapsulation layer 901 reverts back to a relaxed state, the indicator 903 remains in the disengaged state to reveal to a user that the conformal electronic device 900 experienced a deformation that exceeded the deformation limit of at least the indicator 903.

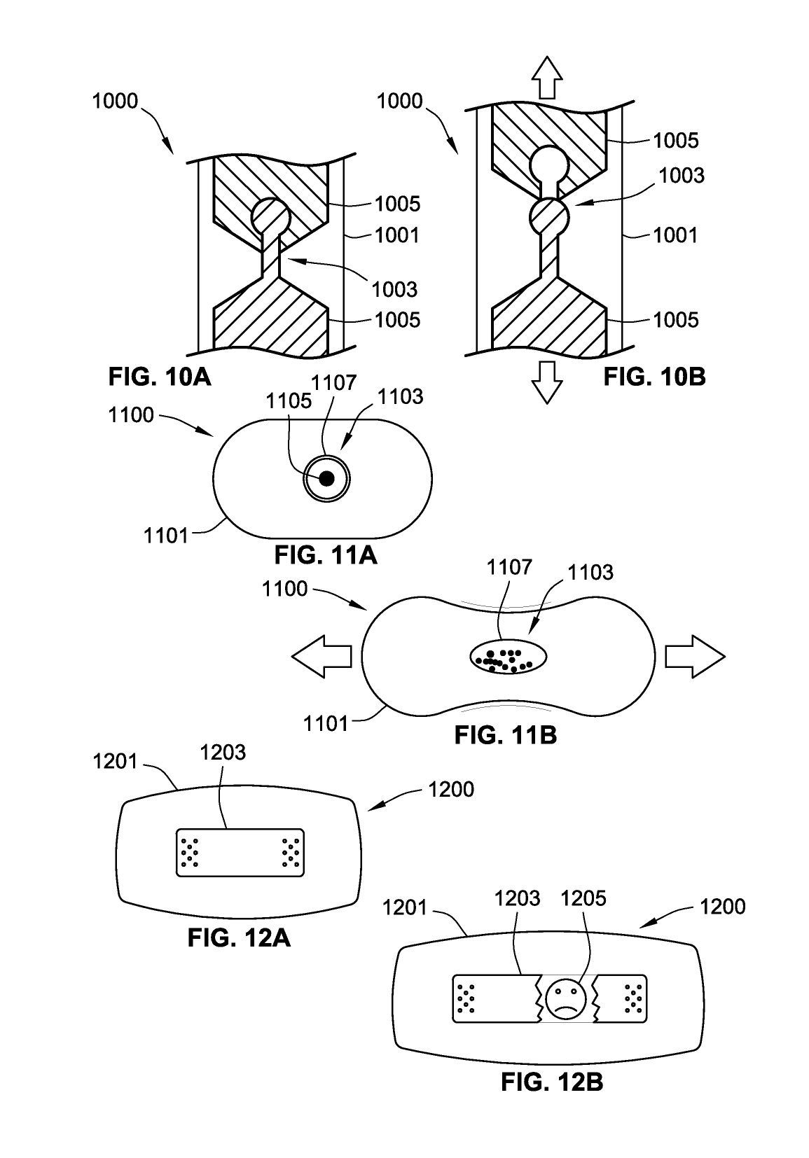

FIGS. 10A and 10B show views of a permanent indicator 1003 of a conformal electronic device 1000, in accord with additional aspects of the present concepts. The conformal electronic device 1000 includes an encapsulation layer 1001. Embedded in and/or affixed to the encapsulation layer 1001 is an indicator 1003 in the form of a knuckle and socket. The indicator 1003 can be formed of two pieces 1005 that interlock, with one piece including the knuckle and the other piece including the socket. In a relaxed state prior to being deformed to a deformation threshold, the indicator 1003 is in an interlocked state with the knuckle interlocked with the socket. As shown in FIG. 10B, upon the conformal electronic device 1000 being deformed beyond a deformation limit, such as to a deformation threshold that is above the deformation limit, the indicator 1003 unlocks from the interlocked position of the pieces 1005 (e.g., the knuckle comes out of the socket). The indicator 1003 remains in the unlocked position despite the conformal electronic device 1000 returning to a relaxed state. This indicates (e.g., to a user) that the conformal electronic device 1000 experienced a deformation that exceeded a deformation limit.

FIGS. 11A and 11B show views of an indicator 1103 of a conformal electronic device 1100, in accord with additional aspects of the present concepts. The conformal electronic device 1100 can be, for example, a patch that is worn on a user. The conformal electronic device 1100 includes an encapsulation layer 1101. Embedded within the encapsulation layer 1101 is an indicator 1103. The indicator 1103 includes a capsule 1105 filled with a dye that is within a chamber 1107. However, the capsule 1105 can be filled with other material that is contrasted to the material within the chamber 1107 (or the absence of material within the chamber 1105), without departing from the spirit and scope of the present disclosure.

As shown in FIG. 11B, upon the encapsulation layer 1101 of the conformal electronic device 1100 experiencing a deformation that satisfies a deformation threshold of the indicator 1103, the capsule 1105 breaks allowing the dye to fill the empty areas of the chamber 1107. By way of example, the capsule 1105 of the indicator 1103 is configured to break at a deformation threshold that exceeds the deformation limit of one or more of the conformal electronic device 1100, the encapsulation layer 1101, and the electronics (not shown) within the conformal electronic device 1100. The dye from the capsule 1105 within the chamber 1107 indicates that at least the capsule 1105 of the indicator 1103 experienced a deformation that satisfied a deformation threshold, and that, for example, exceeded a deformation limit of the conformal electronic device 1100.

FIGS. 12A and 12B show views of a permanent indicator 1205 of a conformal electronic device 1200, in accord with additional aspects of the present concepts. As shown in FIG. 12A, the conformal electronic device 1200 includes an encapsulation layer 1201. The encapsulation layer 1201 includes a top layer 1203 that is above an indicator 1205 (FIG. 12B). In a relaxed state in which the conformal electronic device 1200 has not experienced a deformation threshold of the top layer 1203 and/or indicator 1205, the top layer 1203 of the encapsulation layer 1201 covers the indicator 1205.

Adverting to FIG. 12B, upon exposing the conformal electronic device 1200 to a deformation that satisfies the deformation threshold of the top layer 1203, the top layer 1203 tears and reveals the indicator 1205 below. By way of example, the top layer 1203 of the encapsulation layer 1201 is configured to break at a deformation threshold that exceeds the deformation limit of one or more of the conformal electronic device 1200, the encapsulation layer 1201, and the electronics (not shown) within the conformal electronic device 1200.

The above-described indicators show various examples of mechanical indicators to provide visual, auditory, and tactile indications of deformation. According to some embodiments, an indicator can be in the form of an electrical indicator, and may be integrated into one or more components of the electronics of a conformal electronic device. By way of example, an electrical indicator can provide an electrical response to deformation of a conformal electronic device. The electrical response may be in the form of, for example, a signal that activates a light (e.g., red warning light) on the conformal electronic device or on a device in communication with the conformal electronic device, such as a smartphone.

According to additional embodiments, the conformal electronic device can include a processor as one of the components of the electronics. Responsive to a specified amount of deformation, the processor can execute computer-program code stored on one or more processor-readable mediums to transmit a communication (e.g., a text message, email message, etc.) to a computing device. The communication can visually and/or audibly indicate, as an indicator, that the conformal electronic device is being deformed according to a deformation threshold and may be approaching a deformation limit. As a non-limiting example, the computing device can be one or more smartphones, tablets, laptops, slates, e-readers (or other electronic readers), hand-held or worn computing devices, an Xbox®, a Wii®, or other game systems.

While disclosed primarily as a mechanical deformation, according to some aspects of the present concepts, a deformation also can include chemical and/or thermal deformations and/or exposures of a conformal electronic device. By way of example, and without limitation, chemical exposure can include exposing a conformal electronic device to moisture or other liquids and/or gases that can damage and/or affect the operation of the conformal electronic device. Further, by way of example, and without limitation, thermal exposure can include exposing the conformal electronic device to temperatures outside of normal operating conditions, such as high and/or low temperatures. According to some embodiments, such thermal exposure can further include exposing the conformal electronic device to such temperatures for beyond a threshold period of time.

With respect to chemical deformation indicators, the encapsulation layer of the conformal electronic device can include one or more materials that react when exposed to one or more chemicals. By way of example, and without limitation, a material (e.g., indicator) that reacts when exposed to water can be integrated within the encapsulation layer. Such an indicator indicates possible water damage to the conformal electronic device, such as from being dropped in the sink and/or left in a wash cycle. Additionally, or in the alternative, such an indicator can provide an indication of the current function and/or use of the conformal electronic device. By way of example, a chemical deformation indicator can indicate and/or determine when a conformal electronic device is being worn while swimming or when the conformal electronic device is worn in the shower.

With respect to thermal exposure, a temperature-sensitive material can be incorporated into a portion of the conformal electronic device, such as the encapsulation layer, to provide the temperature indications with respect to thermal deformation thresholds. By way of example, and without limitation, the temperature sensitive material can be a shape memory alloy (such as nitinol), a material that undergoes a glass transition with a temperature change, a piezoelectric material, or a thermoelectric material.

According to some embodiments, the conformal electronic device can be subject to high temperatures (such as but not limited to a hot day in the car or a radiator or heater) or low temperatures (a winter day or in a cooler). In response to the thermal deformation, the heat-sensitive material can crack, such as a glass transition causing the material to become brittle and crack, or may change shape, such as a shape memory alloy changing from straight and flexible to curled and stiff.

According to additional embodiments, the heat-sensitive material may change conductivity states as a result of exposure to the undesirable temperature (such as for the thermoelectric material or the piezoelectric material). As described above, the change in conductivity state can constitute an electrical indicator that is registered by a component of the electronics of the conformal electronic device (e.g., a processor and/or a light). According to some embodiments, on receipt of the electrical indicator, an alert can be sent to the user, such as to the user's computing device (e.g., smartphone, tablet, etc.). Additionally, or as an alternative, a record can be stored to memory of the conformal electronic device to indicate that the device was subjected to the undesirable temperature condition.

According to some embodiments, the conformal electronic device can include a strain limiter. The strain limiter is operable to vary a displacement of the encapsulation layer, one or more electronic components, the conformal electronic device, or a combination thereof in response to a deformation applied to the conformal electronic device. The strain limiter prevents and/or prohibits additional deformation or displacement of the conformal electronic device upon the addition of more strain or a deforming force on the conformal electronic device.

The strain limiter can be formed on the conformal electronic device or can be integrated into a portion (or the entire) conformal electronic device. By way of example, the strain limiter can be integrated into the encapsulation layer of the conformal electronic device. The strain limiter provides added resistance to deformation of the conformal electronic device to prevent a user from deforming the conformal electronic device beyond a deformation threshold. The strain limiter can provide different rates or functions of resistance as the user deforms the conformal electronic device. The different rates or functions of resistance can depend on the desired performance characteristics of the conformal electronic device. Accordingly, the strain limiter allows a user to deform a conformal electronic device until a deformation threshold is reached, such as, but not limited to, a percentage of stretch. The desired deformation threshold is selected to prevent the user from causing failure of, or otherwise damaging, the operational characteristics of the conformal electronic device. Upon reaching the deformation threshold, for example, the strain limiter functions to prevent additional deformation of the conformal electronic device.

According to some embodiments, a strain limiter can provide resistance in response to deformation according to a linear function or rate. Based on the linear function or rate, a user feels a constant resistance in response to deforming a conformal electronic device. The resistance can remain constant until reaching a deformation threshold. Upon reaching the deformation threshold, the strain limiter is configured to increase the resistance to deformation such that additional force does not deform (or minimally deforms) the conformal electronic device. The increase in the resistance can be drastic, such as a hard stop, in which additional force added to deform the conformal electronic device provides little to no deformation (e.g., no additional displacement). According to some embodiments, the increase in the resistance can prohibit a user from further deforming (e.g., such as displacing lengthwise by stretching) the conformal electronic device.

According to some embodiments, a strain limiter can provide resistance in response to deformation forces according to an exponential function or rate. At small deformation forces, the strain limiter provides no resistance (or minimal resistance) to the deformation. The user is free to deform the conformal electronic device at lower deformation forces without feeling resistance of the strain limiter. However, the resistance provided by the strain limiter grows exponentially with increased deformation forces. The exponential growth can be configured to occur at a deformation threshold of the conformal electronic device, the electronics, the encapsulation layer, or a combination thereof. According to some embodiments, the exponential growth in the resistance can prohibit a user from further deforming (e.g., displacing lengthwise by stretching) the conformal electronic device. The transition from no resistance (or minimal resistance) to resistance, such as at a hard stop, allows a user to feel unrestrained with respect to the conformal electronic device until reaching the deformation threshold, rather than feeling constantly restrained until the deformation threshold based on a strain limiter that provides a constant resistance.

By way of example, and without limitation, the transition from no resistance to resistance (e.g., a hard stop) for a strain limiter based on an exponential function or rate can be at a percentage, such as 30%. Accordingly, this percentage, as well as the percentage of deformation for when the hard stop occurs, can vary depending on the performance characteristics of the conformal electronic device.

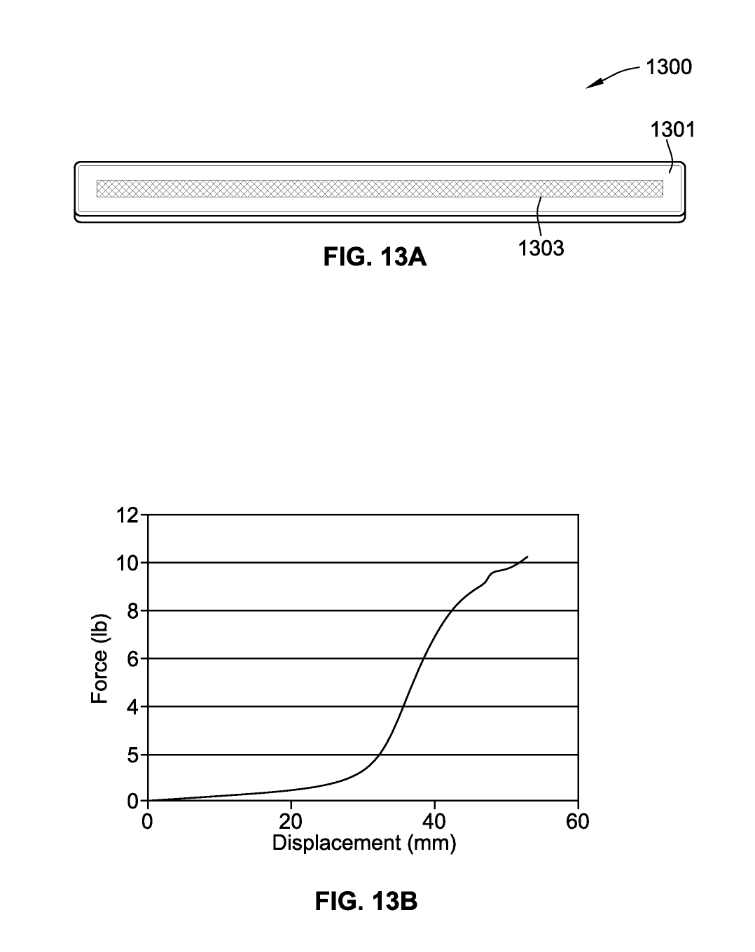

FIG. 13A shows a strain limiter 1303 of a conformal electronic device 1300, in accord with aspects of the present concepts. Specifically, FIG. 13A shows a conformal electronic device 1300 with an encapsulation layer 1301 and a strain limiter 1303. The strain limiter 1303 can be encapsulated within the encapsulation layer 1301, or can be on a surface of the encapsulation layer 1301.

The strain limiter 1303 provides resistance to deformation forces according to an exponential function or rate. Accordingly, FIG. 13B shows a plot of the displacement (along the x-axis) of the strain limiter 1303 of FIG. 13A versus the force applied (along the y-axis) to the conformal electronic device 1300. Although illustrated and described as a displacement versus force, the function can be exhibited as a deformation percentage (e.g., stretch percentage) versus force. As shown in FIG. 13B, the strain limiter 1303 provides no (or minimal) resistance to deformation forces until a threshold amount of displacement is applied, such as 5 pounds of force. At forces less than 5 pounds of force, the strain limiter 1303 provides minimal resistance. Accordingly, at less than 5 pounds of force, the user does not feel resistance of the strain limiter 1303 and is not constrained by the strain limiter 1303 in deforming the conformal electronic device 1300. However, at forces greater than 5 pounds of force, the strain limiter 1303 requires higher amounts of force to displace the conformal electronic device 1300.

Although described and illustrated with respect to FIG. 13B as exhibiting an exponential function of deformation with respect to force, the strain limiter 1303 may instead exhibit a linear function of deformation with respect to force. According to such an embodiment, the curve of FIG. 13B changes such that lower displacements (e.g., between 0 and 20 mm) require larger forces. Accordingly, a user feels a constant resistance with respect to deforming the conformal electronic device. Although the function of deformation versus force may vary between, for example, linear and exponential to vary the feel to a user in deforming the device, both functions can include the same upper limit as, for example, a hard stop to prevent a user from further deforming the device. The upper limit can vary based on the desired deformation characteristics of the conformal electronic device, such as a large maximum displacement or a small maximum displacement.

With the strain limiter of FIG. 13A integrated into the conformal electronic device 1300, the conformal electronic device 1300 exhibits similar displacement (e.g., stretching) behavior. The strain limiter 1303 prevents a user from stretching the conformal electronic device 1300 beyond a desired limit as set by the strain limiter 1303, such as, for example, a displacement of 35-40 mm. In contrast, without the strain limiter 1303, a user can deform (e.g., stretch) the conformal electronic device 1300 to such a degree that the conformal electronic device 1300 can fail, such as the encapsulation layer 1301 failing and/or the electronics (not shown) within the conformal electronic device 1300 no longer functioning.

According to some embodiments, by increasing a response to deformation according to a step-function behavior, such as the step in the exponential function of FIG. 13B, the user can feel the difference in the amount of force required to deform (e.g., stretch, bend, compress, and/or twist) the conformal electronic device 1300. Thus, according to some embodiments, the strain limiter 1303 can function to both limit the strain applied to the conformal electronic device 1300 and to indicate (e.g., as an indicator) a deformation threshold to a user. Such a deformation threshold may constitute the extent of stretching before destructive breakage or other damage to the conformal electronic device 1300 (e.g., reaching the deformation limit of the conformal electronic device 1300).

The materials that form the strain limiter are configured to control the deformation in one (e.g., unilateral) or multiple (e.g., bilateral, multi-lateral) directions. According to some embodiments, the strain limiter is formed of a fabric. The fabric is selected such that it does not impede the conformal nature of the conformal electronic device. According to a fabric strain limiter, different types of fabrics (or textiles) can be used to achieve different force profiles. Woven fabrics exhibit the illustrated force versus displacement profile within FIG. 13B. Such woven fabrics include, for example, denim, linen, cotton twill, satin, chiffon, corduroy, tweed, and canvas. Stretchable fabrics (or textiles) exhibit a more linear (or non-stepwise response) increase in displacement in response to an applied force. However, stretchable fabrics may still serve to limit the strain placed on a conformal electronic device by a user. Such stretchable fabrics include, for example, lycra, knit, jersey, stretch satin, and stretch poplin fabric.

A conformal electronic device as described herein can include any combination of one or more of an auditory indicator, a visual indicator, and a tactile indicator, including one or more elements that generate an auditory indication, a visual indication, and a tactile indication with respect to an external device, in addition to one or more strain limiters. Moreover, according to some embodiments, a strain limiter can also embody an indicator for indicating a deformation threshold.

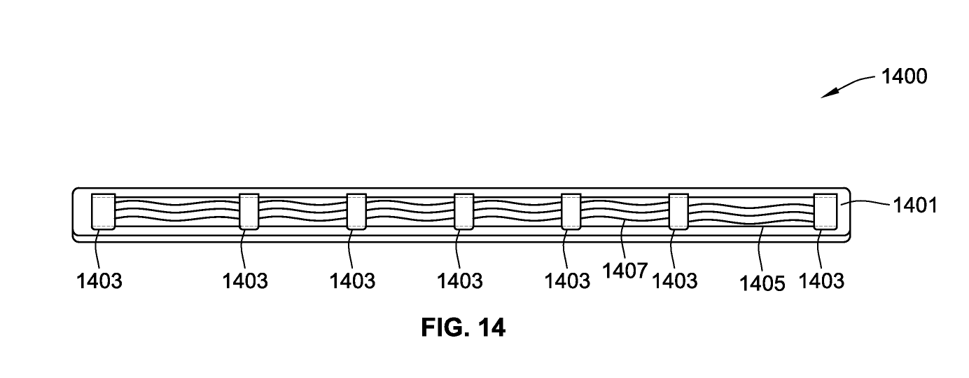

FIG. 14 shows a conformal electronic device 1400 with a strain limiter 1405, in accord with aspects of the present concepts. The conformal electronic device 1400 includes an encapsulation material 1401 that encapsulates electronics 1403 (e.g., device islands). The encapsulation material 1401 further encapsulates the strain limiter 1405. The strain limiter 1405 is operable to vary a displacement of the conformal electronic device 1400 in response to deformation force. According to some embodiments, the strain limiter 1405 may provide a step-wise response to deformation, with one or more step corresponding to a large increase in the amount of force required to displace the stain limiter 1405. Thus, such steps may provide a tactile indication of a deformation threshold.

The conformal electronic device 1400 of FIG. 14 is shown in a deformed (e.g., stretched state), such as at a deformation threshold. Accordingly, the strain limiter 1405 can further include an indicator 1407, which indicates a deformation threshold. The deformation threshold indicated by the indicator 1407 can correspond to the same or different deformation threshold associated with one or more step-wise increases in force versus displacement of the strain limiter 1405. Accordingly, the strain limiter 1405 is configured to vary the displacement of the conformal electronic device 1400 in response to deformation and to indicate a deformation threshold based on the indicator 1407 embodied on the strain limiter 1405. By way of example, as the conformal electronic device 1400 is deformed, the thickness of the encapsulation layer 1401 decreases, which reveals the indicator 1407 on the stain limiter 1405, in conjunction with the action of the strain limiter 1405 in regulating the deformation by varying displacement.

Although illustrated and described with respect to the strain limiter 1405 including the indicator 1407, according to some embodiments, a conformal electronic device (e.g., conformal electronic device 1400) can include an indicator that is separate from a strain limiter. By way of example, any one of the indictors described herein can be formed in a conformal electronic device with a separate strain limiter.

While particular embodiments and applications of the present disclosure have been illustrated and described, it is to be understood that the present disclosure is not limited to the precise construction and compositions disclosed herein and that various modifications, changes, and variations can be apparent from the foregoing descriptions without departing from the spirit and scope of the invention as defined in the appended claims. More generally, those skilled in the art will readily appreciate that all parameters, dimensions, materials, and configurations described herein are meant to be examples and that the actual parameters, dimensions, materials, and/or configurations will depend upon the specific application or applications for which the teachings is/are used. Those skilled in the art will recognize, or be able to ascertain using no more than routine experimentation, many equivalents to the specific inventive embodiments described herein. It is, therefore, to be understood that the foregoing embodiments are presented by way of example only and that embodiments may be practiced otherwise than as specifically described. Embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present disclosure.

What is claimed is:

1. A conformal electronic device comprising:
electronics operable to measure one or more parameters of an object on which the conformal device is disposed on or proximate to;
a conformal layer that encapsulates the electronics; and
a deformation indicator configured to indicate a deformation threshold of the electronics, the conformal layer, the conformal device, or a combination thereof.

2. The conformal electronic device according to claim 1, wherein a thickness of the conformal layer is configured to reveal the deformation indicator at the deformation threshold.

3. The conformal electronic device according to claim 2, wherein the deformation threshold is a threshold of the electronics, and the thickness of the conformal layer is configured to reveal the deformation indicator upon a deformation of the conformal device at the deformation threshold.

4. The conformal electronic device according to claim 1, wherein a thickness of the conformal layer relative surrounding the deformation indicator is configured to reveal the deformation indicator, and the deformation threshold is above the deformation limit of the conformal electronic device.

5. The conformal electronic device according to claim 1, wherein the deformation indicator comprises a plurality of interconnects that connect components of the electronics.

6. The conformal electronic device according to claim 5, the electronics comprising:
a plurality of discrete device islands,
wherein the plurality of interconnects electrically connect two or more of the plurality of discrete device islands.

7. The conformal electronic device according to claim 1, wherein the deformation indicator comprises a visual deformation indicator, an auditory deformation indicator, a tactile deformation indicator, or a combination thereof.

8. The conformal electronic device according to claim 1, wherein the electronics comprise:
a piezoelectric material configured to generate an electric charge in response to a deformation of the conformal device,
wherein the deformation indicator is operable to indicate the deformation threshold based, at least in part, on the electric charge.

9. The conformal electronic device according to claim 1, wherein the deformation threshold is with respect to a mechanical deformation, a chemical deformation, a thermal deformation, or a combination thereof.

10. The conformal electronic device according to claim 1, wherein the deformation indicator is configured to change a surface configuration of the conformal layer at the deformation threshold.

11. A conformal electronic device comprising:
a conformal substrate;
one or more electronic components disposed on and/or within the conformal substrate, the one or more electronic components being operable to measure one or more parameters of a user wearing the conformal device; and
a strain limiter operable to vary a displacement of the conformal substrate, the one or more electronic components, the conformal electronic device, or a combination thereof in response to a deformation applied to the conformal electronic device.

12. The conformal electronic device according to claim 11, wherein the strain limiter is operable to vary the displacement of the conformal substrate, the one or more electronic components, the conformal electronic device, or a combination thereof according to a stepwise function in response to the deformation of the conformal electronic device.

13. The conformal electronic device according to claim 12, wherein a step in the stepwise function corresponds to a deformation threshold of the conformal substrate, the one or more electronic components, the conformal electronic device, or a combination thereof.

14. The conformal electronic device according to claim 11, wherein the strain limiter is configured to prevent displacement of the conformal electronic device at or above a deformation threshold.

15. The conformal electronic device according to claim 11, wherein the strain limiter is formed of a woven fabric.

16. The conformal electronic device according to claim 15, wherein the woven fabric comprises denim, linen, cotton twill, satin, chiffon, corduroy, tweed, canvas, or a combination thereof.

17. The conformal electronic device according to claim 11, wherein the strain limiter is operable to limit the displacement of the conformal device in multiple directions.

18. A conformal electronic device comprising:
one or more electronic components, the one or more electronic components being operable to measure one or more parameters of a user wearing the conformal device;
a conformal encapsulation layer surrounding the one or more electronics;
a deformation indicator, the deformation indicator configured to indicate a deformation threshold of the conformal electronic device,
wherein the encapsulation layer is operable to reveal the deformation indicator at the deformation threshold of the conformal electronic device.

19. The conformal electronic device according to claim 18, wherein the encapsulation layer comprises the deformation indicator as one or more indicia that appear on the encapsulation layer at the deformation threshold of the conformal electronic device.

20. The conformal electronic device according to claim 18, wherein the one or more indicia comprise one or more designed cracks, gaps, or a combination thereof in the encapsulation layer.
